(19) United States
(12) Patent Application Publication
(10) Pub. No.: US 2015/0227667 A1
(43) Pub. Date: Aug. 13, 2015

(54) TEMPERATURE-BASED WIRE ROUTING

(71) Applicant: QUALCOMM Incorporated, San Diego, CA (US)

(72) Inventor: Chunchen Liu, San Diego, CA (US)

(73) Assignee: QUALCOMM Incorporated, San Diego, CA (US)

(21) Appl. No.: 14/175,429

(22) Filed: Feb. 7, 2014

(51) Int. Cl. G06F 17/50; H05K 3/00; H05K 1/02

(52) U.S. Cl. CPC G06F 17/5077; H05K 1/0201; H05K 1/0296; H05K 3/0005

(57) ABSTRACT

A circuit design scheme routes wires based on temperature. In particular, temperature conditions along a prospective route are taken into account when determining whether to use that route for a wire. For example, a route can be selected from among a set of prospective routes based on which route is associated with the “smoothest” temperature gradient. Here, preference may be given to the route or routes having the smallest amount of temperature variation along the route.

### TECHNICAL FIELD

The following relates generally to circuit design and more specifically, but not exclusively, to routing a wire based on temperature.

### BACKGROUND

Algorithms for routing wires, sometimes referred to as traces or electrical paths, on or within printed circuit boards (PCBs), integrated circuits (ICs), or other structures attempt to find the routes that best meet the routing requirements for the wires. In general, routing requirements dictate that the wires should be as short as possible. In this way, power consumption and signal propagation delay associated with the transmission of a signal over a wire is minimized at least to some degree. Moreover, the use of shorter wires enables more wires to be routed within a given area, thereby improving circuit density.

In some applications, routing requirements specify that the lengths of multiple wires be equal or nearly equal. For example, in timing critical applications that employ clock trees or that employ parallel wires (e.g., for busses or differential signals), the use of equal wire lengths makes it easier to match the signal propagation characteristics of the wires. Consequently, a signal or signals from one or more data sources may reach multiple data sinks via different wires at approximately the same time, thereby maintaining a desired timing relationship between the signals at the data sinks. In other words, matched wires are employed to keep the relative timing skew of signals transmitted over different wires to a minimum.

Other techniques have been proposed to reduce timing skew. For example, some systems use buffers to control the delay along a wire and thereby reduce timing skew. Other system insert crosslinks into the wiring structure to reduce timing skew.

In practice, however, the above techniques may not sufficiently reduce timing skew or may have certain drawbacks. For example, various operating conditions and environmental factors may affect the propagation delay of a signal through a wire. Thus, it may be difficult to match the signal propagation characteristics of different wires, even if the wire lengths are matched. Also, active techniques such as buffer insertion, can lead to a significant increase in power consumption. In addition, as crosslink link insertion can increase the wire length, an increase in power consumption may be seen in these scenarios as well. In view of the above, a need exists for improved circuit design techniques.

### BRIEF SUMMARY OF SOME EXAMPLES

The following summarizes some aspects of the disclosure to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a summary form as a prelude to the more detailed description that is presented later.

Various aspects of the disclosure provide for routing wires based on temperature. That is, temperature conditions along a prospective route are taken into account when determining whether to use that route for a wire. In general, there is direct relationship between the temperature of a wire and the resistance of the wire. Consequently, temperature differences along a wire may significantly affect propagation delay through the wire. In accordance with some aspects of the disclosure, a route is selected from among a set of prospective routes based on which route is associated with the “smoothest” temperature gradient. For example, preference may be given to the route or routes having the smallest amount of temperature variation along the route. In some scenarios, the use of such a routing scheme results in the identification of a route associated with the lowest signal skew. In some scenarios, the use of such a routing scheme involves selecting multiple routes such that the signal skews of the routes match (e.g., for routes of different lines of a parallel bus, or for routes of different branches of a clock tree).

In accordance with some aspects of the disclosure, a routing scheme uses a temperature-based correlation maps to select a route for a trace. Initially, a grid of route points is defined over an area (e.g., a rectangular area) within which a trace can be routed from a first endpoint (e.g., a signal source point, a branch point, or a signal sink point) to a second endpoint (e.g., a signal sink point). The routing scheme then uses simulations or other techniques to determine the temperature characteristic of each point. The routing scheme then generates a spatial correlation matrix (map) where each entry corresponds to one of the prospective route points. Next, the routing scheme generates a correlation cofactor matrix (map) for these points based on the spatial correlation map. Each entry in the correlation cofactor map indicates the correlation between the temperature characteristics of the corresponding route point and the two endpoints. Thus, the best route can be identified by determining which route encompasses route points that collectively have the highest correlation with the endpoints.

The disclosure relates in some aspects to selecting a route based on temperature conditions over time. For example, the temperature at each prospective route point may be collected over a period of time. Thus, the spatial correlation matrix referred to above can be a temporal variant spatial correlation matrix in some implementations. Temperature-based correlation between prospective route points may thus take temperature trends or other temporal temperature conditions into account.

The disclosure also relates in some aspects to avoiding temperature extremes when selecting a route. For example, in some implementations, the selection of a route requires that any so-called hot spots within a prospective routing area be avoided.

Further aspects of the disclosure provide a routing apparatus that includes a memory device and a processing circuit coupled to the memory device. The processing circuit is configured to identify a plurality of prospective routes for routing a wire through at least one substrate; determine, for each of the prospective routes, a temperature characteristic associated with the prospective route; select one of the prospective routes based on the temperature characteristics of the prospective routes; and store an indication of the selected route in the memory device.

Still further aspects of the disclosure provide a method for wireless communication including receiving at least one signal indicative of an area for routing a wire through at least one substrate; identifying a plurality of prospective routes for routing the wire within the area; determining, for each of the prospective routes, a temperature characteristic associated with the prospective route; selecting one of the prospective routes based on the temperature characteristics of the prospective routes; and storing an indication of the selected route.

Additional aspects of the disclosure provide a routing apparatus including means for identifying a plurality of prospective routes for routing a wire through at least one substrate; means for determining, for each of the prospective routes, a temperature characteristic associated with the prospective route; means for selecting one of the prospective routes based on the temperature characteristics of the prospective routes; and means for storing an indication of the selected route.

Other aspects of the disclosure provide a non-transitory machine-readable storage medium having instructions stored thereon which when executed by a processing circuit cause the processing circuit to: identify a plurality of prospective routes for routing a wire through at least one substrate; determine, for each of the prospective routes, a temperature characteristic associated with the prospective route; select one of the prospective routes based on the temperature characteristics of the prospective routes; and store an indication of the selected route.

In addition, other aspects of the disclosure provide a substrate having a wire formed thereon along a selected route associated with a smoothest temperature gradient from among a plurality of prospective routes. The substrate is prepared by a process comprising: identifying the plurality of prospective routes for routing the wire on the substrate; determining, for each of the prospective routes, a temperature gradient associated with the prospective route; selecting one of the prospective routes based on which of the prospective routes has the smoothest temperature gradient of the prospective routes; providing the substrate; and forming the wire on the substrate according to the selected route.

Examples of other aspects of the disclosure related to the above follow. The routing of the wire may be between a first endpoint and a second endpoint. In this case, the selection of one of the prospective routes may comprise determining which prospective route has a highest temperature correlation with the first and second endpoints. Also, the determination of the temperature characteristics may comprise determining, for each point of a set of points along a corresponding prospective route, a temperature correlation between the point and the first and second endpoints. Similarly, the determination of the temperature gradients may comprise determining, for each point of a set of points along a corresponding prospective route, a temperature correlation between the point and the first and second endpoints. In either case, the selection of one of the prospective routes may comprise determining which set of points has a highest collective temperature correlation with the first and second endpoints. The selection of one of the prospective routes may comprise rejecting any of the prospective routes that pass through an area of the at least one substrate associated with a temperature that exceeds a threshold temperature and/or a temperature that falls below a threshold temperature. Thus, the selected route might not traverse any area of the at least one substrate associated with a temperature that exceeds a threshold temperature and/or a temperature that falls below a threshold temperature. In addition, one branch point of a plurality of prospective branch points between the first and second endpoints may be selected based on which prospective branch point has a highest temperature correlation with the first and second endpoints. Also, the at least one substrate may comprise a printed circuit board substrate, an integrated circuit die substrate, or some other type of substrate.

The disclosure relates in some aspects to identifying a grid of points on the at least one substrate. In this case, the identification of the plurality of prospective routes may comprise identifying routes within the grid of points, wherein the routing of the wire is between a first endpoint and a second endpoint within the grid of points. The determination of the temperature characteristics associated with the prospective routes and/or the determination of the temperature gradient may comprise: determining, for each of the points of the grid of points, a temperature characteristic of the point; generating a spatial correlation matrix corresponding to the grid of points based on the temperature characteristics of the points; generating a correlation cofactor matrix based on the spatial correlation matrix, wherein the correlation cofactor matrix correlates, for each of the points of the grid of points, the temperature characteristic of the point with the temperature characteristics of the first and second endpoints; and determining, for each prospective route, a temperature correlation between the prospective route and the first and second endpoints based on the correlation cofactor matrix. Also, the selection of one of the prospective routes may comprise determining which prospective route has a highest temperature correlation with the first and second endpoints. In addition, the determination of the temperature characteristics of the points may be based on a determination of at least one temperature characteristic of at least one electronic circuit to be located in a vicinity of the grid of points.

The selection of one of the prospective routes may be based on additional criteria. For example, upon determining, for each of the prospective routes, a distance associated with the prospective route, the selection of one of the prospective routes may be based on the distances associated with the prospective routes. As another example, upon identifying at least one prospective route that traverses at least two of a plurality of routing layers, the selection of one of the prospective routes may involve applying a weighting factor to each prospective route that traverses at least two of the plurality of routing layers. Thus, the smoothest temperature gradient may be associated with one of the prospective routes that traverses at least two of the plurality of routing layers. As yet another example, upon identifying at least one prospective route that traverses a via between at least two of a plurality of routing layers, the selection of one of the prospective routes may involve applying a weighting factor to each prospective route that traverses a via between at least two of the plurality of routing layers. Thus, the smoothest temperature gradient may be associated with one of the prospective routes that traverses a via between at least two the plurality of routing layers. As a further example, upon identifying at least one prospective route that reverses course, the selection of one of the prospective routes may involve applying a weighting factor to each prospective route that reverses course. Accordingly, the smoothest temperature gradient may be associated with one of the prospective routes that reverses course. In some aspects, the at least one substrate may comprise a plurality of stacked substrates. In this case, the plurality of routes may be identified over the plurality of stacked substrates.

In some aspects, the selected route comprises a first endpoint and a second endpoint. Here, the smoothest temperature gradient may correspond to a highest correlation in temperature with the first and second endpoints along the selected route. Also, the smoothest temperature gradient may correspond to a highest consistency of a temperature characteristic along the selected route. The selected route also may comprise a branch point, where the branch point is associated with a highest temperature correlation with the first and second endpoints from among a plurality of prospective branch points located between the first and second endpoints.

These and other aspects of the disclosure will become more fully understood upon a review of the detailed description, which follows. Other aspects, features, and implementations of the disclosure will become apparent to those of ordinary skill in the art, upon reviewing the following description of specific, exemplary implementations of the disclosure in conjunction with the accompanying figures. While features of the disclosure may be discussed relative to certain implementations and figures below, all implementations of the disclosure can include one or more of the advantageous features discussed herein. In other words, while one or more implementations may be discussed as having certain advantageous features, one or more of such features may also be used in accordance with the various implementations of the disclosure discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 is a diagram illustrating an example of route selection based on temperature in accordance with some aspects of the disclosure.

FIGS. 2 and 3 are diagrams illustrating an example of temperature-induced skew.

FIG. 4 is a flowchart illustrating an example of a wire routing method in accordance with some aspects of the disclosure.

FIG. 5 is a diagram illustrating an example of route selection based on a temperature cofactor matrix in accordance with some aspects of the disclosure.

FIG. 6 is a diagram illustrating an example of generating and using a cofactor matrix in accordance with some aspects of the disclosure.

FIG. 7 is a diagram illustrating an example of a substrate in accordance with some aspects of the disclosure.

FIG. 8 is a diagram illustrating another example of a substrate in accordance with some aspects of the disclosure.

FIG. 9 is a diagram illustrating an example of a scenario where a layer-based weighting factor may be applied in accordance with some aspects of the disclosure.

FIG. 10 is a diagram illustrating an example of a scenario where a via-based weighting factor may be applied in accordance with some aspects of the disclosure.

FIG. 11 is a diagram illustrating an example of a scenario where a course reversal-based weighting factor may be applied in accordance with some aspects of the disclosure.

FIGS. 12 and 13 are diagrams illustrating an example of a route decision considering both temperature correlation and route distance in accordance with some aspects of the disclosure.

FIG. 14 is a diagram illustrating an example of a clock tree routed in accordance with some aspects of the disclosure.

FIG. 15 is a diagram illustrating an example of a differential pair routed in accordance with some aspects of the disclosure.

FIG. 16 is a flowchart illustrating an example of a maze routing method in accordance with some aspects of the disclosure.

FIG. 17 is a block diagram illustrating an example of a circuit design system in which one or more aspects of the disclosure may find application.

FIG. 18 is a block diagram illustrating select components of an apparatus configured to provide routing functionality in accordance with some aspects of the disclosure.

FIG. 19 is a flowchart illustrating a wire routing method in accordance with some aspects of the disclosure.

FIG. 20 is a flowchart illustrating a process for preparing a substrate having a wire formed thereon in accordance with some aspects of the disclosure.

FIG. 21 is a flowchart illustrating additional aspects of a wire routing method in accordance with some aspects of the disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

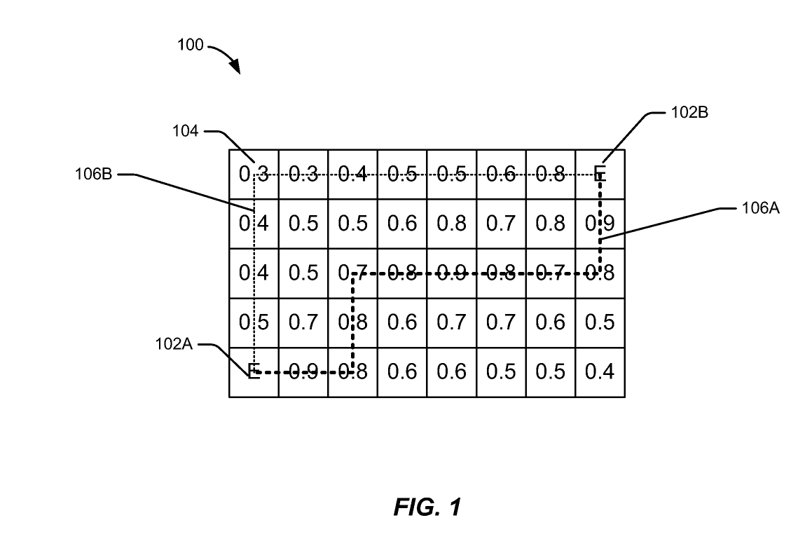

FIG. 1 illustrates an example of route selection based on temperature in accordance with some aspects of the disclosure. A grid of route points 100 is defined for routing a wire from a first endpoint 102A to a second endpoint 102B. Each route point is represented by one of the boxes in the grid of route points 100. Thus, there are 40 route points in the example of FIG. 1. In practice, a given route point would typically be located at the center of the corresponding box.

As discussed in more detail below, the route selection scheme involves determining (e.g., estimating) a temperature characteristic associated with each route point. Based on these temperature characteristics, a determination is made regarding the extent to which the temperature characteristic of each route point correlates with the temperature characteristics of the first and second endpoints 102A and 102B. In the example of FIG. 1, the number in a given box represents a temperature correlation cofactor for that box, where 0.99 would represent approximately total temperature correlation and 0.0 would represent no temperature correlation. Thus, a first routing point 104 in the grid of routing points 100 has a temperature correlation cofactor of 0.3 with the first and second endpoints 102A and 102B. It should be appreciated that different correlation cofactor ranges (e.g., including values less than 0 or greater than 1) could be used in different implementations.

In accordance with the teachings herein, the route between the first and second endpoints 102A and 102B is selected by determining which route of all of the possible routes between the first and second endpoints 102A and 102B has the best temperature correlation with the first and second endpoints 102A and 102B. Continuing with the example of FIG. 1, the best route would thus be the route that collectively has the highest correlation cofactors. Accordingly, the route represented by a first dashed line 106A is selected over any other prospective route such as the route represented by a second dashed line 106B.

The routing scheme of FIG. 1 may thus address timing skew issues that arise from different temperature conditions that exist over a route between a pair of endpoints. For example, component workload differences in printed circuit boards (PCBs), integrated circuits (ICs), or other circuitry can result in non-uniform temperature gradients across prospective routing paths. As a specific example, when the workload of a processor is very high, the area around the processor on a PCB, in an IC, etc., would typically be hotter than other areas of the PCB or IC. Given the linear relationship between wire resistance and temperature, a high temperature variance can increase the propagation delay over a wire by, for example, as much as 100%.

Moreover, the temperatures in a given area can vary over time. In the presence of a significant temperature gradient, uncertainty may thus be imparted on the system in terms of propagation delay, timing skew (e.g., clock skew), and skew variation. Furthermore, when interconnects are globally routed over a PCB, an IC, etc., the delay and skew effects of these temperature gradients may be even more problematic.

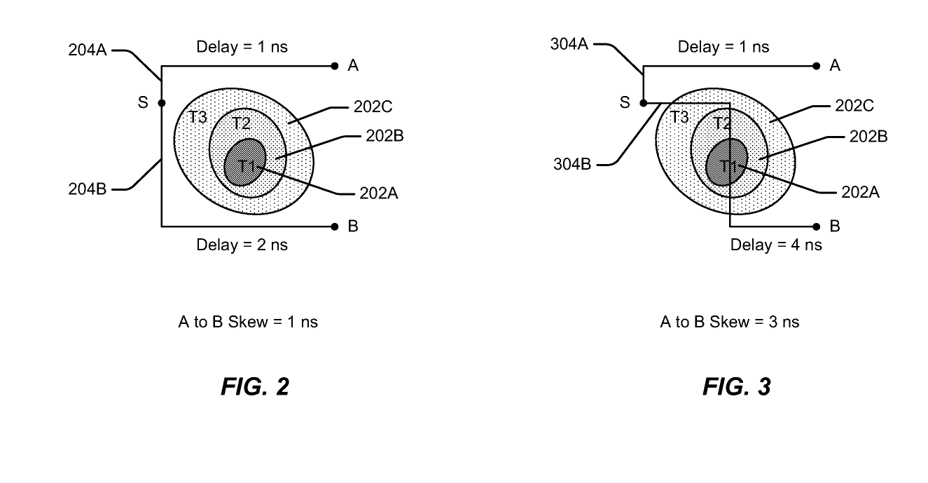

FIGS. 2 and 3 illustrate a simplified example of a routing area that is subject to different temperatures. A first area 202A is subjected to a relatively high temperature of T1 degrees during operation of circuitry in the vicinity of the first area 202A. To reduce the complexity of FIGS. 2 and 3, this circuitry is not shown. A second area 202B is subjected to a temperature of T2 degrees that is lower than T1 degrees during operation of the nearby circuitry. A third area 202C is subjected to a temperature of T3 degrees that is lower than T2 degrees during operation of the nearby circuitry.

In general, there is direct relationship between the temperature of a wire and the resistance of the wire. Consequently, temperatures differences along a wire may significantly affect propagation delay through the wire. FIGS. 2 and 3 illustrate an example of an increase in propagation delay that can arise when a wire passes through areas of high temperature.

In FIG. 2, a signal generated at a source point S propagates to a first sink point A via a first wire segment 204A and to a second sink point B via a second wire segment 204B. The propagation delay from the source point S to the first sink point A is 1 nanosecond, while the propagation delay from the source point S to the second sink point B is 2 nanoseconds. Of note, neither the first wire segment 204A nor the second wire segment 204B passes through any of the first to third areas 202A-202C.

In FIG. 3, a first wire segment 304A does not pass through any of the first to third areas 202A-202C. However, a second wire segment 304B does pass through each of the first to third areas 202A-202C. Consequently, in FIG. 3, the propagation delay from the source point S to the second sink point B is 4 nanoseconds. Accordingly, FIGS. 2 and 3 illustrate that a significant temperature-induced timing skew can arise between the signals carried on different wires (e.g., discrete wires or different branches of a tree) if the route for one of the wires passes through an area that is subject to different temperatures than another one of the wires.

The disclosure relates in some aspects to minimizing temperature-induced timing skew and timing skew variations through the use of a thermal-aware routing scheme. Advantageously, such a thermal-aware routing scheme effectively reduces skew and skew variation without additional metal routing and/or without an increase in power consumption in contrast to buffer insertion, crosslink insertion, and other conventional skew mitigation techniques.

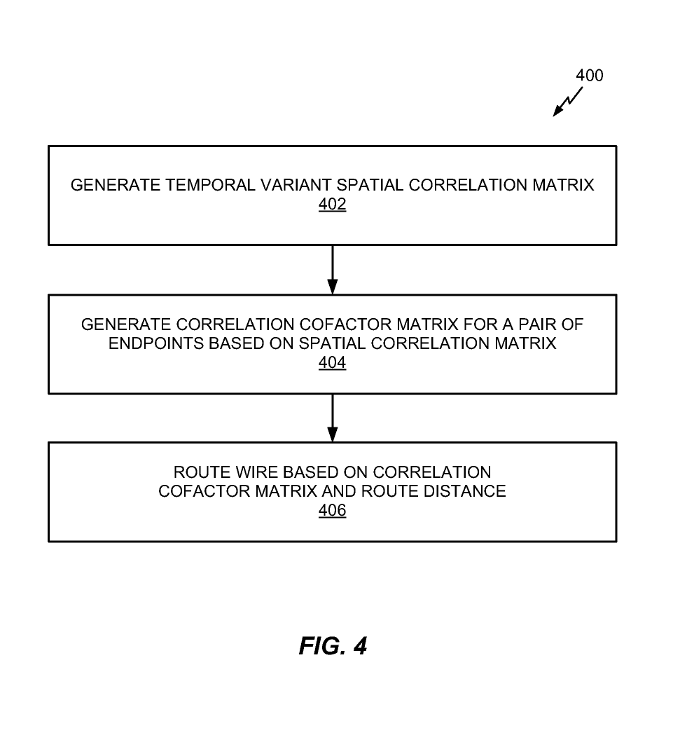

With the above in mind, examples of operations relating to thermal-aware routing functionality according to the disclosure will be described in more detail in conjunction with the flowchart of FIG. 4. For convenience, the operations of FIG. 4 (or any other operations discussed or taught herein) may be described as being performed by specific components. It should be appreciated, however, that in various implementations these operations may be performed by other types of components and may be performed using a different number of components. It also should be appreciated that one or more of the operations described herein may not be employed in a given implementation.

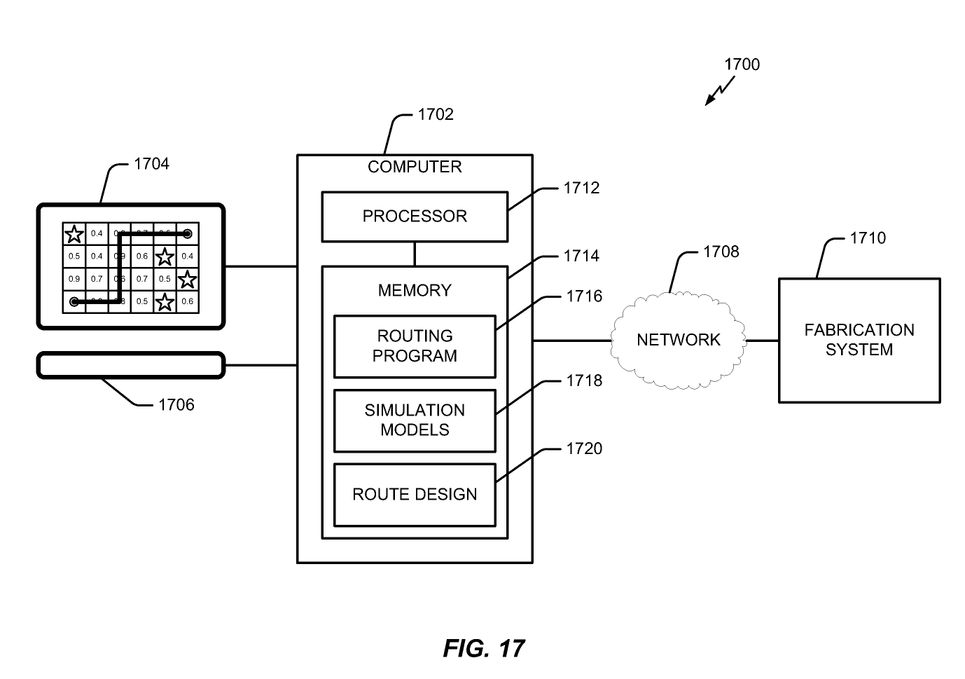

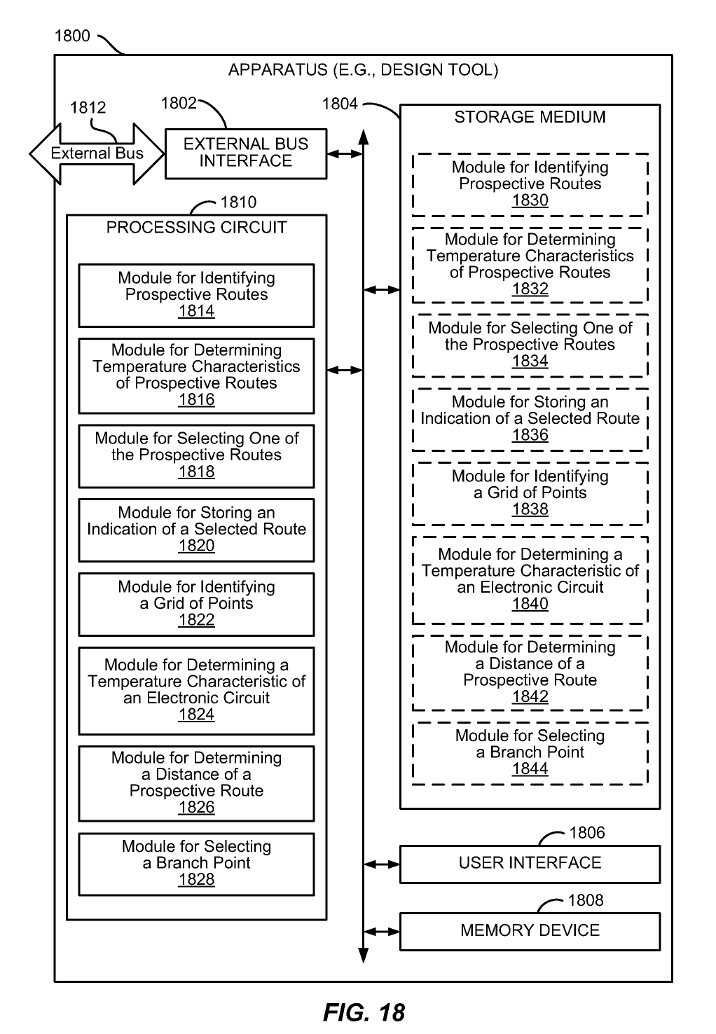

FIG. 4 illustrates a process 400 for routing a wire based on a correlation cofactor matrix in accordance with some aspects of the disclosure. The process 400 may take place within a processing circuit 1810 (FIG. 18), which may be located in a circuit design tool or some other suitable apparatus. In another aspect, the process 400 may be implemented by the circuit design system 1700 illustrated in FIG. 17. Of course, in various aspects within the scope of the disclosure, the process 400 may be implemented by any suitable apparatus capable of supporting wire routing operations.

An example of an objective that may be achieved by the process 400 is to find the route for a wire that has the smoothest temperature gradient and that also results in as short of a wire as possible. In some aspects, a smooth temperature gradient refers to one that does not have any or has few sudden changes in temperature (e.g., changes in temperature magnitude that exceed a first threshold level) and that does not have large temperature extremes (e.g., a difference in temperature magnitude that exceeds a second threshold level that is larger in magnitude than the first threshold level). By providing a smooth temperature gradient, skew and skew variation that could otherwise be caused by temperature variations along a route can be kept low. In addition, by keeping the wire length short (e.g., through the use of maze routing), the power consumption associated with the wire can be kept low.

In some implementations, the process 400 is used to find a route between endpoints (e.g., pin pairs) that are highly correlated with respect to temperature. For example, this routing scheme may be particularly advantageous for scenarios where both endpoints tend to be at or near the same temperature over time.

In general, the process 400 attempts to find the route that has the highest temperature correlation with the endpoints. Thus, the route selection process attempts to build all routing paths on highly correlated areas. By building on such highly correlated areas, any changes in temperature seen over the course of the route will tend to be smoother (e.g., the magnitude of any temperature changes will be lower). Consequently, timing skew and skew variations associated with a route may be more controlled or predictable.

Further to this end, the process 400 also may avoid so-called hot spots. For example, the route selection process may ensure that the selected route does not pass through any area subject to a temperature extreme (i.e., either too hot or too cold).

At block 402, a temporal variant spatial correlation matrix (map) is generated. Here, the routing area (e.g., the overall PCB or IC) is divided into a uniform grid with a total of N nodes. The temperatures at each of the N nodes are then modeled by, for example, random processes. Each node is thus described by a temperature sequence sampled at N time instances as indicated by Equation 1.

$${L}_{n 1} = \{ T ( {t}_{1} , {n}_{1} ) , … , T ( {t}_{p} , {n}_{1} ) , T ( {t}_{p + 1} , {n}_{1} ) , … , T ( {t}_{N} , {n}_{1} ) \} \\ {L}_{n 2} = \{ T ( {t}_{1} , {n}_{2} ) , … , T ( {t}_{p} , {n}_{2} ) , T ( {t}_{p + 1} , {n}_{2} ) , … , T ( {t}_{N} , {n}_{2} ) \} \\ … \\ {L}_{n N} = \{ T ( {t}_{1} , {n}_{N} ) , … , T ( {t}_{p} , {n}_{N} ) , T ( {t}_{p + 1} , {n}_{N} ) , … , T ( {t}_{N} , {n}_{N} ) \} \qquad ( 1 )$$

A temperature (spatial) correlation matrix can thus be defined as set forth in Equation 2.

$$C ( i , j ) = \frac{cov ( i , j )}{{σ}_{i} \cdot {σ}_{j}} \qquad ( 2 )$$

Here, cov(i,j) is the co-variance matrix between the nodes as set forth in Equation 3.

cov(i,j)=Σₖ₌₁^{N}T(tₖ,nᵢ)T(tₖ,nⱼ)−Σₖ₌₁^{N}T(tₖ,nᵢ)Σₖ₌₁^{N}T(tₖ,nⱼ) (3)

The parameters σᵢ and σⱼ referenced in Equation 1 and set forth in Equation 4 are the standard deviations for the nodes nᵢ and nⱼ, respectively.

$${σ}_{i} = \sqrt{{\sum }_{k = 1}^{N} \frac{{T ( {t}_{k} , {n}_{i} )}^{2}}{N} - {( {\hat{T}}_{i} )}^{2}} \\ {σ}_{j} = \sqrt{{\sum }_{k = 1}^{N} \frac{{T ( {t}_{k} , {n}_{j} )}^{2}}{N} - {( {\hat{T}}_{j} )}^{2}} \qquad ( 4 )$$

Finally, the mean temperatures for the nodes nᵢ and nⱼ, respectively, are set forth in Equation 5.

$${\hat{T}}_{i} = {\sum }_{k = 1}^{N} \frac{T ( {t}_{k} , {n}_{i} )}{N} \\ {\hat{T}}_{j} = {\sum }_{k = 1}^{N} \frac{T ( {t}_{k} , {n}_{j} )}{N} \qquad ( 5 )$$

At block 404 of FIG. 4, a correlation cofactor matrix (map) is generated based on the spatial correlation matrix generated at block 402. As discussed herein, in some aspects, this operation involves determining the temperature correlation of each point in the grid with respect to the designated wire target points (e.g., endpoints).

A correlation cofactor in area P (CCp) to target i, j is defined based on (e.g., as the product of or as the sum of) the two corresponding coefficients. For the case where the correlation cofactor is based on the product of the coefficients, CCp=cov(i,p)*cov(p,j). Again, areas with a high correlation cofactor value represent high correlation with both routing target points.

At block 406, the wire is routed based on the correlation cofactor matrix and the route distance. In some implementations, a routing algorithm such as a maze routing algorithm is used in conjunction with the thermal ware routing in an attempt to find the shortest possible route with the smoothest possible temperature gradient.

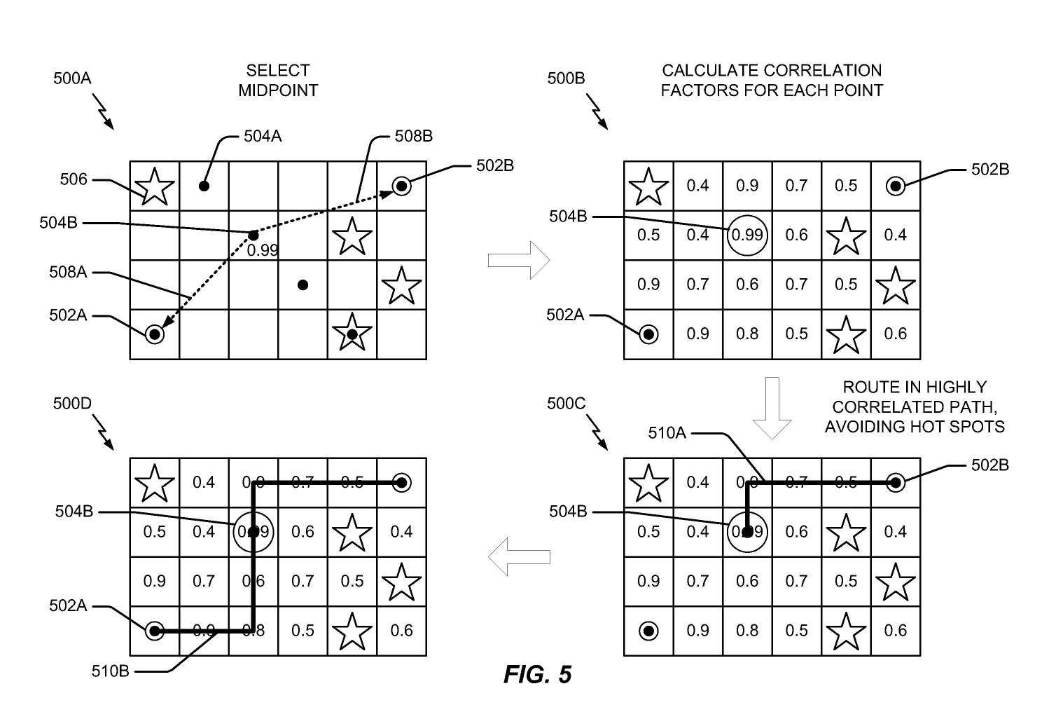

FIG. 5 illustrates, in a graphical manner, an example of route selection based on a correlation cofactor matrix. FIG. 5 depicts the grid at four different phases of the route selection labeled, in order of operation, a first phase 500A, a second phase 500B, a third phase 500C, and a fourth phase 500D.

In this example, the first phase 500A involves selecting a midpoint between a first endpoint 502A and a second endpoint 502B. To this end, a set of four prospective midpoints are identified, each represented by a single solid dot. For purposes of illustration, a first midpoint 504A and a second midpoint 504B are specially labeled in FIG. 5. The temperature correlation cofactors are calculated for each of the prospective midpoints and, preferably, the prospective midpoint with the highest temperature correlation to the first and second endpoints 502A and 502B is selected as the midpoint for the route. In this example, the second midpoint 504B has a correlation cofactor of 0.99 and, hence, this midpoint is selected as the midpoint for the routing operation. The correlation cofactors of the other prospective midpoints are not labeled to reduce the complexity of FIG. 5.

As mentioned above, in some implementations, the routing operation avoids so-called hot spots. Hot spots are represented as stars in FIG. 5. For purposes of illustration, a first one of these hot spots 506 is specially labeled. It should be appreciated that in some scenarios, the presence of a hot spot may prevent the selection of an otherwise desired midpoint. For example, hot spots may block a direct route to a midpoint.

Once the selected midpoint 504B is selected for the route, a route passing through the second midpoint 504B needs to be identified. Specifically, the route selection involves identifying a route from the second midpoint 504B to the first endpoint 502A, as generally represented by a first dashed line 508A. In addition, the route selection involves identifying a route from the second midpoint 504B to the second endpoint 502B, as generally represented by a second dashed line 508B.

To this end, the routing operation proceeds to the second phase 500B whereby a correlation cofactor is calculated for each routing point. As in FIG. 1, the correlation cofactor may range from 0.0 to approximately 1.0 (e.g., 0.9999). As a visual aid, a circle has been added to the second midpoint 504B to emphasize that this routing point is the midpoint for the route.

The routing operation then proceeds to the third phase 500C where a desired route 510A between the second midpoint 504B and the second endpoint 502B is identified. As discussed herein, the route having the highest correlation cofactor values is selected here. Also, hot spots are avoided during this route selection.

Finally, the routing operation proceeds to the fourth phase 500D where a desired route 510B between the second midpoint 504B and the first endpoint 502A is identified. Again, the route having the highest correlation cofactor values is selected. In addition, hot spots are avoided.

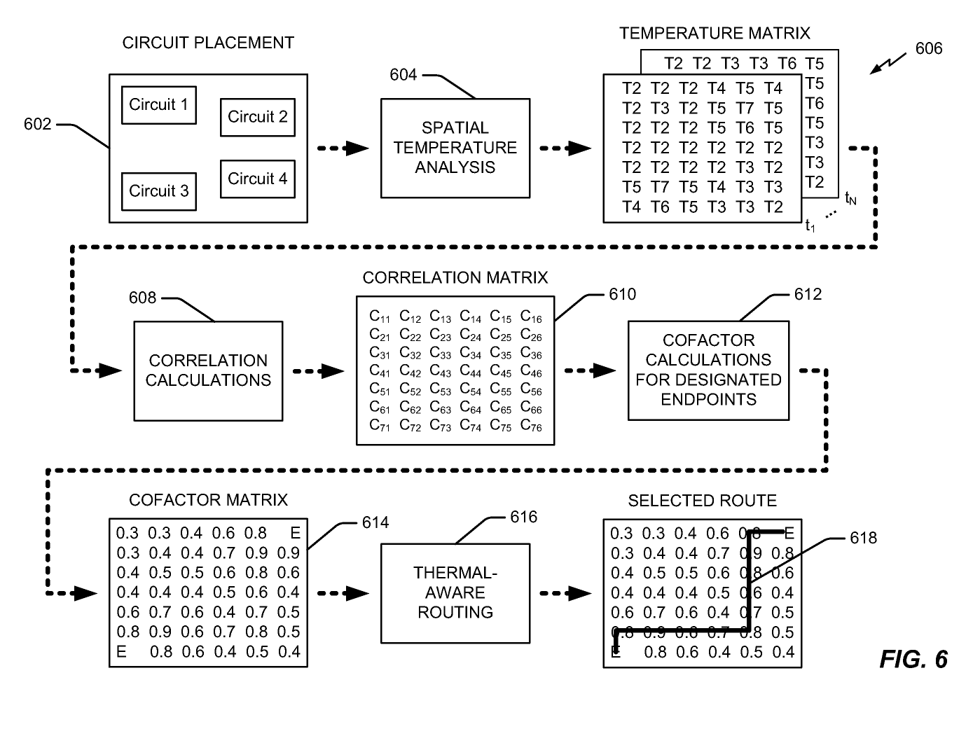

Referring now to FIG. 6, the generation and use of a cofactor matrix will be described in more detail. As mentioned above, high temperature variability can significantly impact the delay and skew associated with a wire route. Thermal-aware routing as taught herein may consider both distance and temperature correlation for evaluating the delay between each node and also reducing skew and skew variation.

Since dynamic temperature variation over time generates different skews, the routing scheme identifies the smoothest routing path, from a temperature perspective, in an attempt to guarantee more stable skew variation. The routing scheme considers time variant temperature variations along with spatial and temporal correlation. A temperature correlation map is then generated by analyzing time variant temperature maps. In this way, the routing scheme can identify the route with the highest correlation cofactor values and thereby provide a route with better thermal tolerance. In addition, by avoiding any hot spot areas indicated by the temperature correlation map, the routing scheme can further reduce worst case skew.

Initially, a circuit design process involves locating circuits in an area 602 of a PCB, IC, or some other suitable structure. This may be accomplished, for example, using an appropriate computer aided design (CAD) system.

Spatial temperature analysis 604 is then performed for the area 602. In some aspects, this involves determining (e.g., estimating) the temperature at different points of the area 602 over a period of time. For example, a simulation program that has information about the temperature characteristic of the circuits located in the area 602 and information about how these circuits are configured to operate can generate an estimate of the temperature to be expected at various points within the area 602 when the circuits are in operation.

To model such time variant temperatures in the vicinity of the circuits in the area 602, a grid is defined on the PCB, IC, or other routing structure and each grid is assigned a temperature range. This temperature range can be obtained by measurement or thermal simulation. For example, the circuits can be run though all operational states (e.g., a complete instruction set for the circuits may be tested) to obtain the corresponding temperature profiles.

As a specific, non-limiting example, temperature analysis may involve a micro-architecture level power and temperature simulation. The section 602 is divided into a uniform grid with a total of N nodes. By applying appropriate benchmark applications in a sequence (each with a time-period tₚ), the thermal-power is obtained by averaging the cycle-accurate (scale of picoseconds) dynamic power in the thermal-constant scale (scale of milliseconds). Using this time-variant thermal power as an input, the transient temperature T(tᵢ,nⱼ) over the area 602 is calculated at different time instants tᵢ for each node nⱼ in the grid. To automatically extract correlation for temperature variations, the temperatures at N nodes may be modeled by random processes. Each node in the grid may thus be described by a temperature sequence sampled at N time instants. FIG. 6 illustrates a simplified example of a resulting three dimensional temperature matrix 606 for time instances t₁ to t_{N}. In a non-limiting example, the temperature matrix 606 corresponds to Equation 1 set forth above.

Correlation calculations 608 use the temperature matrix 606 as an input to generate a correlation matrix 610. In a non-limiting example, the correlation calculations 608 correspond to Equations 2-5 set forth above. In such a case, the correlation matrix 610 would thus correspond to Equation 2. For example, the correlation coefficients C(i, j) can be pre-computed and stored in a table.

Cofactor calculations 612 use the correlation matrix 610 as an input to generate a cofactor matrix 614 associated with designated target points (e.g., endpoints) for the route. A point in the grid having a high correlation cofactor value represents high correlation with both routing target points. As mentioned above, in some implementations, a correlation cofactor is based on the product of the coefficients associated with two target points: CCp=cov(i,p)*cov(p,j). In other implementations, a correlation cofactor may be based on the sum of the coefficients, CCp=cov(i,p)+cov(p,j). Other algorithms that serve to indicate the correlation of a point with two target points could be used as well.

Finally, thermal-aware routing 616 uses the cofactor matrix 614 as an input to identify the route 618 with the highest correlation values. For example, the thermal-aware routing 616 may calculate a correlation value for each prospective route between two target points. The correlation value for a route is a function of the individual cofactor values associated with the grid points along the route. For example, the individual cofactor values may be multiplied together, added together, or operated on in some other way to generate the correlation value for the route.

Various types of routing algorithms (e.g., maze routing, etc.) may be employed in various implementations depending on design objectives. Thermal-aware routing may employ Manhattan routing rules or other routing rules. Thus, routing need not be restricted to “upward” and “to the right” routing choices, or necessarily restricted to remain within a defined routing window. Thus, course reversal (e.g., backtracking) could be employed in a scenario where this results in superior skew characteristics for a route.

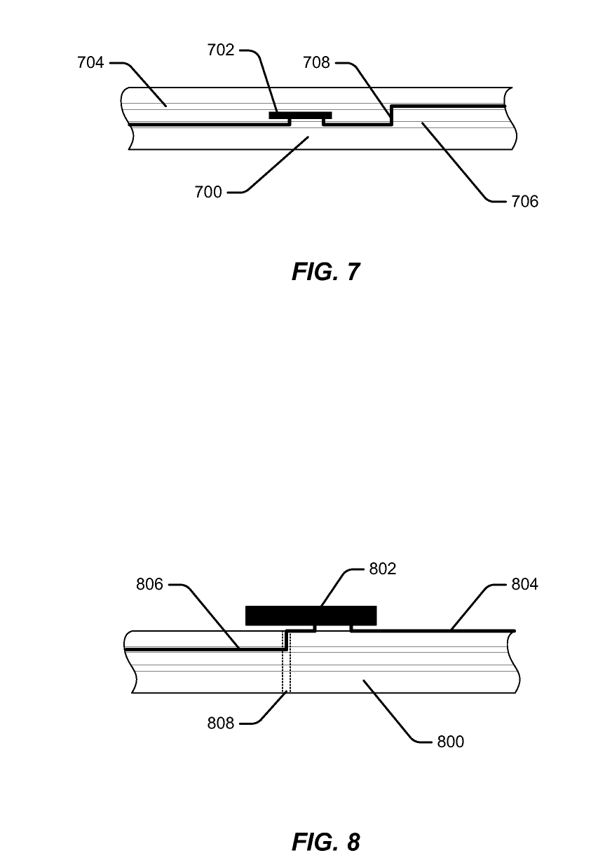

Temperature-based routing may be used for routing in two or three dimensions. For example, routing may be performed across different layers of a PCB, across different layers of an IC, across stacked ICs, or across some other multi-layer structure. In this case, a temperature map can be calculated for all prospective route points in the different layers and a routing decision made based on this three-dimensional temperature map. FIGS. 7 and 8 illustrate two examples of multi-layer routing (i.e., three-dimensional routing) on two different types of substrates, respectively.

FIG. 7 illustrates a simplified example of routing on an integrated circuit die substrate 700. Through the use of deposition and other fabrication techniques, a circuit 702 and metal wires (traces) are formed on various layers of the substrate 700. In this example, wires are formed on a first metal layer 704 (e.g., a first wire routing layer) and on a second metal layer 706 (e.g., a second wire routing layer). Moreover, if needed, a wire can be routed on multiple layers whereby, at an appropriate location, the wire includes a transition 708 from one layer to another layer.

FIG. 8 illustrates a simplified example of routing on a printed circuit board substrate 800. Through the use of deposition and other fabrication techniques a circuit 802 (a surface mount component in this example) and metal wires (traces) are formed on or attached to various layers of the substrate 800. In this example, wires are formed on a first metal layer 804 (e.g., a first wire routing layer) and on a second metal layer 806 (e.g., a second wire routing layer). Moreover, if needed, a wire can be routed on multiple layers whereby a so-called via 808 electrically couples one section of a wire on one layer to another section of the wire on another layer.

A final routing decision may take physical factors into account as well as temperature factors. For example, weighting factors can be associated with transitions from one layer to another, the use of a via, reversing course, or other physical factors. In some aspects, these physical factors may affect the signal skew, the power consumption, or some other operating parameter associated with a route. Thus, a weighting factor can be used to quantify such an effect. Consequently, the determination of the best route (e.g., the route with the lowest skew, the route that provides a skew that best matches the skew of another route, the route with the lowest power consumption, etc.) can be based on a balancing of temperature correlation and these other weighting factors.

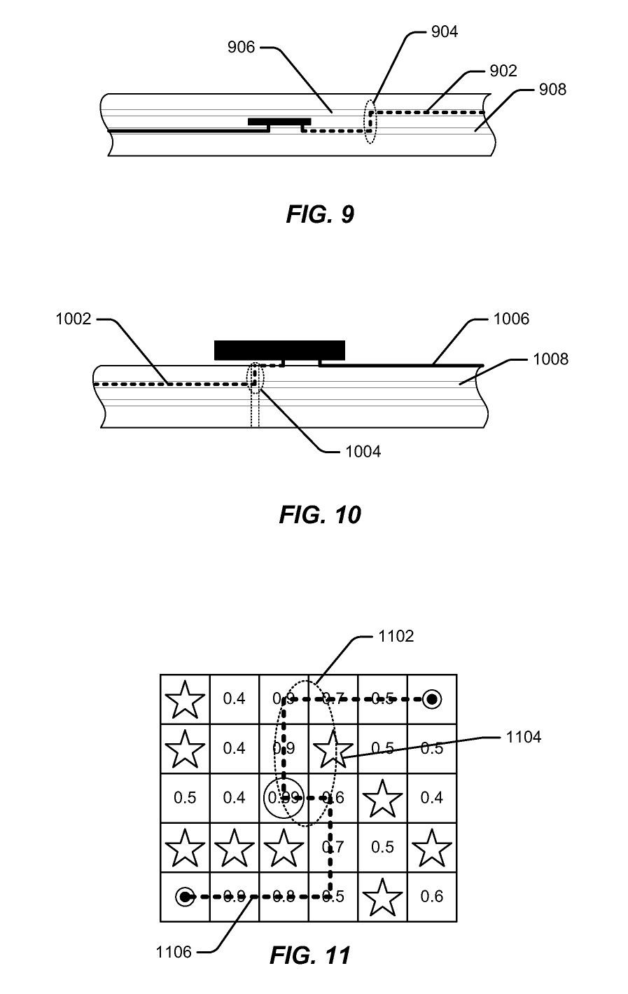

FIG. 9 illustrates an example of a scenario where a routing decision may consider a layer-based weighting factor. A decision to use a particular route may take into account whether the route is on a single layer or multiple layers. In particular, since a transition between layers may negatively affect the signal propagation characteristics of the route (e.g., due to impedance discontinuities), a routing decision may penalize a route that transitions between layers one or more times.

As one example, after calculating a correlation value for a route 902, this correlation value may be adjusted to account for the route 902 including a transition 904 between a first layer 906 and a second layer 908. For example, the original correlation value for the route 902 may be reduced by a weighting factor to indicate that the skew associated with the route 902 is negatively affected by the transition 904.

As another example, a routing decision may be made based on a correlation value for the route 902 as well as one or more weighting factors related to the route 902. Such weighting factors can be indicative of, without limitation, the length of the route 902 and the number of transitions between layers in the route 902. Thus, the route selection algorithm can calculate one or more weighting factors for each of the prospective routes, and use these weighting factors and the correlation values to determine whether to select one route over another route.

FIG. 10 illustrates an example of a scenario where a routing decision may consider a via-based weighting factor. Here, a decision to use a particular route may take into account whether the route passes through a via. Since the use of a via may negatively affect the signal propagation characteristics of the route (e.g., due to impedance discontinuities), a routing decision may penalize a route that uses one or more vias.

As one example, after calculating a correlation value for a route 1002, this correlation value may be adjusted to account for the route 1002 including a via 1004 between a first layer 1006 and a second layer 1008. For example, the original correlation value for the route 1002 may be reduced by a weighting factor to indicate that the skew associated with the route 1002 is negatively affected by the via 1004.

As another example, a routing decision may be made based on a correlation value for the route 1002 as well as one or more weighting factors related to the route 1002. Such weighting factors can be indicative of, without limitation, the length of the route 1002 and the number of vias 1004 in the route 1002. Thus, the route selection algorithm can calculate one or more weighting factors for each of the prospective routes, and use these weighting factors and the correlation values to determine whether to select one route over another route.

FIG. 11 illustrates an example of a scenario where a routing decision may consider a course reversal-based weighting factor. In this scenario, a decision to use a particular route may take into account whether the route reverses its course. Since such a course reversal may negatively affect the signal propagation characteristics of the route (e.g., due to impedance discontinuities, transitioning outside of a desired area, or lengthening of the route), a routing decision may penalize a route that includes one or more course reversals. FIG. 11 illustrates an example of a course reversal 1102 caused by hot spots (e.g., hot spot 1104) that block the use of a more desirable route.

As one example, after calculating a correlation value for a route 1106, this correlation value may be adjusted to account for the route 1106 including a course reversal 1002. For example, the original correlation value for the route 1106 may be reduced by a weighting factor to indicate that the skew associated with the route 1106 is negatively affected by the course reversal 1102.

As another example, a routing decision may be made based on a correlation value for the route 1106 as well as one or more weighting factors related to the route 1106. Such weighting factors can be indicative of, without limitation, the length of the route 1106 and the number of course reversals 1102 in the route 1106. Again, the route selection algorithm can calculate one or more weighting factors for each of the prospective routes, and use these weighting factors and the correlation values to determine whether to select one route over another route.

In some implementations, three-dimensional multi-layer routing is employed over a plurality of stacked substrates. For example, the various layers referred to in FIGS. 7-10 above could be stacked substrates in some scenarios. Thus, the identification of a route as taught herein can involve identifying a route over a plurality of stacked substrates in some implementations.

The disclosure relates in some aspects to selecting a route by balancing temperature considerations and route length considerations. For example, a route that is shorter than an alternative route might not be selected if the alternative route has better temperature characteristics. Conversely, a route that has better temperature characteristic than an alternative route might not be selected if the length of the route is longer than the alternative route. Consequently, the determination of the best route (e.g., the route with the lowest skew, the route that provides a skew that best matches the skew of another route, the route with the lowest power consumption, etc.) can be based on both temperature correlation and distance factors.

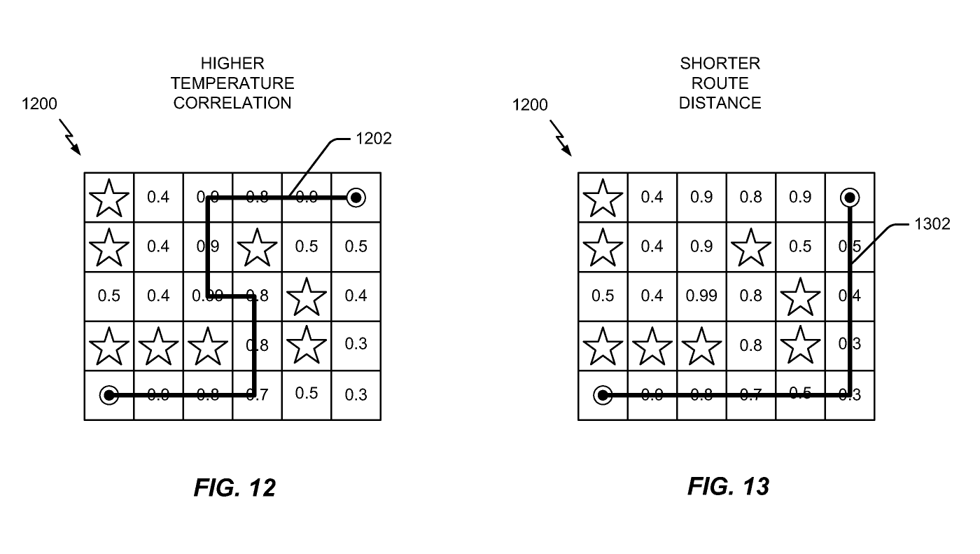

FIGS. 12 and 13 illustrate a scenario where a route decision may consider both temperature correlation and route distance. FIGS. 12 and 13 both illustrate the same correlation matrix 1200, but depict different routes 1202 and 1302, respectively. The route 1202 has a higher temperature correlation than the route 1302, while the route 1302 is shorter than the route 1202.

Accordingly, a routing decision can take into account the length of the route and the temperature correlation of the route to determine which route is better. As discussed herein, factors to consider when identifying the best route can include, without limitation, the amount of skew, a skew match with an associated route, and power consumption.

The manner in which these different factors are compared from one route to the next can take various forms. As one example, a routing scheme can calculate the differences between these factors for the routes 1202 and 1302, and compare these differences (e.g., through the use of a weighting factor) to determine whether the improved temperature correlation of the route 1202 offsets the longer length of the route 1202 in terms of desired performance (e.g., skew, power consumption, etc.). As another example, a routing scheme can calculate a metric for each route 1202 and 1302 that accounts for both temperature correlation and route length. The routing scheme can then compare the metric for the route 1202 with the metric for the route 1302 to identify the best route.

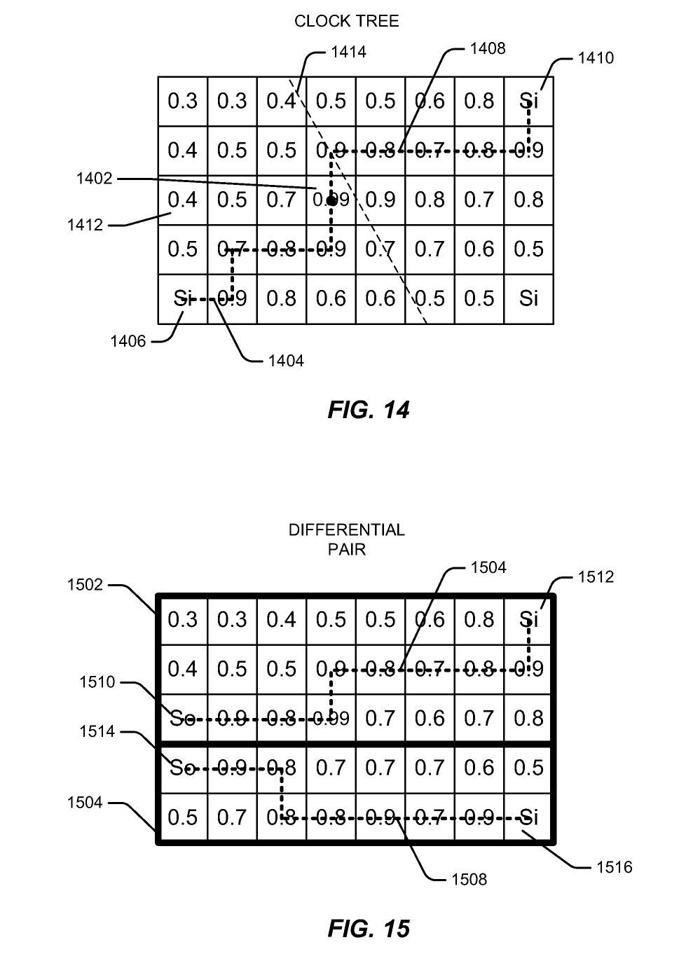

As mentioned above, thermal-aware routing as taught herein may advantageously be used to match the signal propagation characteristics of related wires. Two of these examples will be described in conjunction with FIGS. 14 and 15.

FIG. 14 illustrates an example of a clock tree routed in a manner that places all of the branches of the clock tree on highly temperature correlated paths. A clock signal from a clock source (not shown) is coupled to a branch point 1402. A first branch 1404 of the clock tree is routed from the branch point 1402 to a first sink point 1406. A second branch 1408 of the clock tree is routed from the branch point 1402 to a second sink point 1410. As indicated, the respective routes for the first and second branches 1404 and 1408 are selected to have a high temperature correlation with the first and second sink points 1406 and 1410.

While the discussion herein has often referred to temperature correlation with respect to two target points, a path may be selected based on correlation with a different number of target points. For example, a clock tree may have more than two sink points (e.g., points 1406, 1410, and 1412 in FIG. 14). In such a case, the techniques described herein may be employed to identify a route for multiple branches of the clock tree by identifying a multi-branch route that provides the best temperature correlation along the route with respect to three or more target points (e.g., sink points).

FIG. 15 illustrates an example of a differential pair routed in a manner that places both rails of the differential pair on highly temperature correlated paths. In this example, a first grid 1502 (including the top three rows) is defined for routing a first rail 1504 of a differential pair, and a second grid 1506 (including the bottom two rows) is defined for routing a second rail 1508 of the differential pair.

The first rail 1504 is sourced at a first source point 1510 and sinked at a first sink point 1512. The second rail 1508 is sourced at a second source point 1514 and sinked at a second sink point 1516. As indicated, the respective routes for the first and second rails 1504 and 1508 are each selected to have a high temperature correlation with the corresponding sink and sources points.

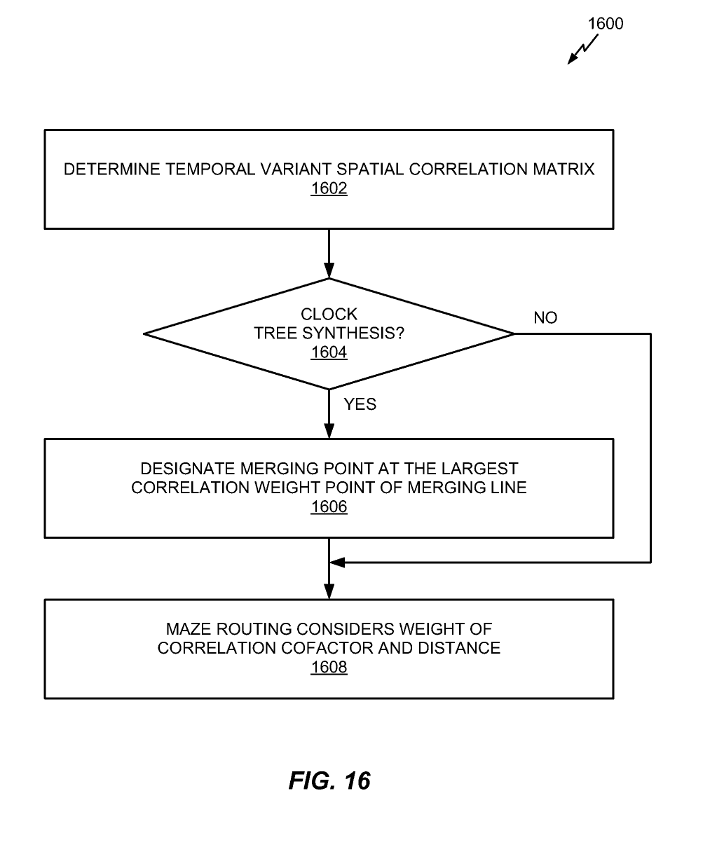

FIG. 16 illustrates an example of a maze routing process 1600 that could be used to route the wires of FIGS. 14 and 15. The process 1600 may take place within a processing circuit 1810 (FIG. 18), which may be located in a circuit design tool or some other suitable apparatus. In another aspect, the process 1600 may be implemented by the circuit design system 1700 illustrated in FIG. 17. Of course, in various aspects within the scope of the disclosure, the process 1600 may be implemented by any suitable apparatus capable of supporting wire routing operations.

At block 1602, a temporal variant spatial correlation matrix (map) is determined. For example, an apparatus may generate the matrix or receive the matrix from another apparatus.

At block 1604, a determination is made as to whether a clock tree is being synthesized. If not (e.g., detail routing is being performed instead of clock tree routing), the operational flow proceeds to block 1608.

If a clock tree is being synthesized, the operational flow proceeds to block 1606 where a merging point for the clock tree is designated. In particular, the merging point is placed at the point in a merging line that has the largest correlation weight and is not a hot spot. In some implementations, a merging line is identified by calculating the Manhattan distance between the target points. FIG. 14 illustrates an example of a merging line 1414 that is equidistant from the first and second sink points 1406 and 1410. The merging line 1414 intersects the prospective merging points in the grid. Thus, the operations of block 1606 may involve determining the correlation cofactor for each of the prospective merging points and selecting the merging point that has the highest correlation weight, provided that prospective merging point is not a hot spot.

At block 1608, maze routing is invoked to identify a route that has the highest correlation cofactor weight, where the route is constrained by the Manhattan distance.

FIG. 17 illustrates an example of a circuit design system 1700 in which one or more aspects of the disclosure may find application. The system 1700 includes a computer 1702 (e.g., a workstation) communicatively coupled to a user display device 1704 and user input devices 1706. The computer 1702 is also communicatively coupled to a network 1708 to enable design data generated by the computer 1702 to be transferred to a fabrication system 1710 that manufactures PCBs, ICs, or the like.

The apparatus 1702 includes a processor 1712 and a memory 1714. The processor 1712 may be any suitable type of processing unit, such as a central processing unit (CPU), a co-processor, an arithmetic processing unit, a graphics processing unit (GPU), a digital signal processor (DSP), etc. The memory 1714 may include any suitable type of memory technology such a RAM, ROM, FLASH, disk drives, and the like.

A routing program 1716 and simulation models 1718 stored in the memory 1714 and/or implemented by the processor 1712 enable a user to generate circuit designs in accordance with the teachings herein. For example, a user may use the display device 1704 and the user input devices to position circuits on at least one substrate (e.g., of an IC or a PCB), simulate temperature characteristics at various locations on the at least one substrate over time, generate a correlation matrix, generate a cofactor matrix, and select a route that has the best temperature correlation as taught herein. The user may then send a resulting route design 1720 to the fabrication system 1710 to produce the desired circuit component.

Turning now to FIG. 18, a block diagram is shown illustrating select components of an apparatus 1800, such as the computer 1702 of FIG. 17, according to at least one example of the disclosure. The apparatus 1800 (e.g., a design tool) includes an external bus interface 1802, a storage medium 1804, a user interface 1806, a memory device 1808, and a processing circuit 1810. The processing circuit is coupled to or placed in electrical communication with each of the external bus interface 1802, the storage medium 1804, the user interface 1806, and the memory device 1808.

The external bus interface 1802 provides an interface for the components of the apparatus 1800 to an external bus 1812. The external bus interface 1802 may include, for example, one or more of: signal driver circuits, signal receiver circuits, amplifiers, signal filters, signal buffers, or other circuitry used to interface with a signaling bus or other types of signaling media.

The processing circuit 1810 is arranged to obtain, process and/or send data, control data access and storage, issue commands, and control other desired operations. The processing circuit 1810 may include circuitry adapted to implement desired programming provided by appropriate media in at least one example. In some instances, the processing circuit 1810 may include circuitry adapted to perform a desired function, with or without implementing programming. By way of example, the processing circuit 1810 may be implemented as one or more processors, one or more controllers, and/or other structure configured to execute executable programming and/or perform a desired function. Examples of the processing circuit 1810 may include a general purpose processor, a digital signal processor (DSP), an application specific integrated circuit (ASIC), a field programmable gate array (FPGA) or other programmable logic component, discrete gate or transistor logic, discrete hardware components, or any combination thereof designed to perform the functions described herein. A general purpose processor may include a microprocessor, as well as any conventional processor, controller, microcontroller, or state machine. The processing circuit 1810 may also be implemented as a combination of computing components, such as a combination of a DSP and a microprocessor, a number of microprocessors, one or more microprocessors in conjunction with a DSP core, an ASIC and a microprocessor, or any other number of varying configurations. These examples of the processing circuit 1810 are for illustration and other suitable configurations within the scope of the disclosure are also contemplated.

The processing circuit 1810 is adapted for processing, including the execution of programming, which may be stored on the storage medium 1804. As used herein, the terms “programming” or “instructions” shall be construed broadly to include without limitation instruction sets, instructions, code, code segments, program code, programs, programming, subprograms, software modules, applications, software applications, software packages, routines, subroutines, objects, executables, threads of execution, procedures, functions, etc., whether referred to as software, firmware, middleware, microcode, hardware description language, or otherwise.

In some instances, the processing circuit 1810 may include one or more of: a module for identifying prospective routes 1814, a module for determining temperature characteristics of prospective routes 1816, a module for selecting one of the prospective routes 1818, a module for storing an indication of a selected route 1820, a module for identifying a grid of points 1822, a module for determining a temperature characteristic of an electronic circuit 1824, a module for determining a distance of a prospective route 1826, or a module for selecting a branch point 1828.

The module for identifying prospective routes 1814 may include circuitry and/or programming (e.g., a module for identifying prospective routes 1830 stored on the storage medium 1804) adapted to collect information about two or more target points within a routing area, calculate different routes that may be traversed within the routing area between the target points, and generate an indication of the prospective routes.

The module for determining temperature characteristics of prospective routes 1816 may include circuitry and/or programming (e.g., a module for determining temperature characteristics of prospective routes 1832 stored on the storage medium 1804) adapted to acquire information about prospective routes, calculate temperature characteristics of various points along each prospective route, and generate an indication of the temperature characteristics.

The module for selecting one of the prospective routes 1818 may include circuitry and/or programming (e.g., a module for selecting one of the prospective routes 1834 stored on the storage medium 1804) adapted to acquire information about temperature characteristics of prospective routes, identify a best temperature characteristic from among the different temperature characteristics, and generate information about the route associated with the best temperature characteristic.

The module for storing an indication of a selected route 1820 may include circuitry and/or programming (e.g., a module for storing an indication of a selected route 1836 stored on the storage medium 1804) adapted to acquire information about a selected route, generate an indication that is indicative of the selected route, generate a signal comprising the indication, and sending the signal to a memory device.

The module for identifying a grid of points 1822 may include circuitry and/or programming (e.g., a module for identifying a grid of points 1838 stored on the storage medium 1804) adapted to acquire information about a routing area for one or more circuits, define a grid of points within that area, and generate an indication of the defined grid of points.

The module for determining a temperature characteristic of an electronic circuit 1824 may include circuitry and/or programming (e.g., a module for determining a temperature characteristic of an electronic circuit 1840 stored on the storage medium 1804) adapted to acquire information about electronic circuits, determine a temperature characteristic of the electronic circuits under one or more operating conditions, and generate an indication of the temperature characteristic.

The module for determining a distance of a prospective route 1826 may include circuitry and/or programming (e.g., a module for determining a distance of a prospective route 1842 stored on the storage medium 1804) adapted to acquire information about a prospective route, calculate a distance of the prospective route, and generate an indication of the distance of the prospective route.

The module for selecting a branch point 1828 may include circuitry and/or programming (e.g., a module for selecting a branch point 1844 stored on the storage medium 1804) adapted to acquire information about a target points, identify prospective branch points between the target points, select one of the prospective branch points, and generate an indication that identifies the selected branch point.

The storage medium 1804 may represent one or more processor-readable devices for storing programming, electronic data, databases, or other digital information. The storage medium 1804 may also be used for storing data that is manipulated by the processing circuit 1810 when executing programming. The storage medium 1804 may be any available media that can be accessed by the processing circuit 1810, including portable or fixed storage devices, optical storage devices, and various other mediums capable of storing, containing and/or carrying programming. By way of example and not limitation, the storage medium 1804 may include a processor-readable storage medium such as a magnetic storage device (e.g., hard disk, floppy disk, magnetic strip), an optical storage medium (e.g., compact disk (CD), digital versatile disk (DVD)), a smart card, a flash memory device (e.g., card, stick, key drive), random access memory (RAM), read only memory (ROM), programmable ROM (PROM), erasable PROM (EPROM), electrically erasable PROM (EEPROM), a register, a removable disk, and/or other mediums for storing programming, as well as any combination thereof. Thus, in some implementations, the storage medium may be a non-transitory (e.g., tangible) storage medium.

The storage medium 1804 may be coupled to the processing circuit 1810 such that the processing circuit 1810 can read information from, and write information to, the storage medium 1804. That is, the storage medium 1804 can be coupled to the processing circuit 1810 so that the storage medium 1804 is at least accessible by the processing circuit 1810, including examples where the storage medium 1804 is integral to the processing circuit 1810 and/or examples where the storage medium 1804 is separate from the processing circuit 1810.

Programming stored by the storage medium 1804, when executed by the processing circuit 1810, causes the processing circuit 1810 to perform one or more of the various functions and/or process steps described herein. For example, the storage medium 1804 may include one or more of: the module for identifying prospective routes 1830, the module for determining temperature characteristics of prospective routes 1832, the module for selecting one of the prospective routes 1834, the module for storing an indication of a selected route 1836, the module for identifying a grid of points 1838, the module for determining a temperature characteristic of an electronic circuit 1840, the module for determining a distance of a prospective route 1842, or the module for selecting a branch point 1844. Thus, according to one or more aspects of the disclosure, the processing circuit 1810 is adapted to perform (in conjunction with the storage medium 1804) any or all of the processes, functions, steps and/or routines for any or all of the apparatuses described herein. As used herein, the term “adapted” in relation to the processing circuit 1810 may refer to the processing circuit 1810 being one or more of configured, employed, implemented, and/or programmed (in conjunction with the storage medium 1804) to perform a particular process, function, step and/or routine according to various features described herein.

The memory device 1808 may represent one or more memory devices and may comprise any of the memory technologies listed above or any other suitable memory technology. The memory device 1808 may store circuit design information such as, without limitation, an indication of a selected route, along with other information used by one or more of the components of the apparatus 1800. The memory device 1808 also may be used for storing data that is manipulated by the processing circuit 1810 or some other component of the apparatus 1800. In some implementations, the memory device 1808 and the storage medium 1804 are implemented as a common memory component.

The user interface 1806 includes functionality that enables a user to interact with the apparatus 1800. For example, the user interface 1806 may interface with one or more user output devices (e.g., a display device, etc.) and one or more user input devices (e.g., a keyboard, a tactile input device, etc.).

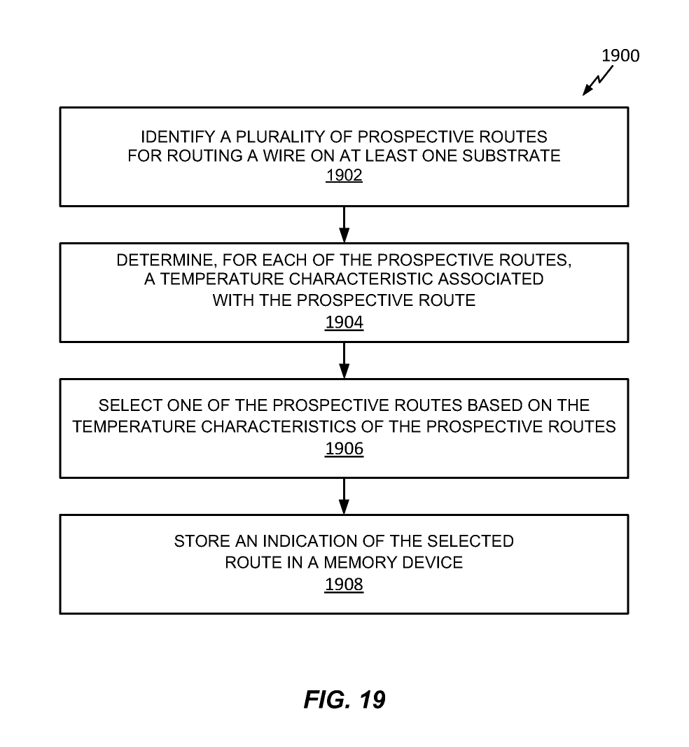

FIG. 19 illustrates a process 1900 for wire routing in accordance with some aspects of the disclosure. The process 1900 may take place within a processing circuit 1810 (FIG. 18), which may be located in a circuit design tool or some other suitable apparatus. In another aspect, the process 1900 may be implemented by the circuit design system 1700 illustrated in FIG. 17. Of course, in various aspects within the scope of the disclosure, the process 1900 may be implemented by any suitable apparatus capable of supporting wire routing operations.

At block 1902, prospective routes for routing a wire on at least one substrate are identified. For example, different routes for a wire between a first endpoint and a second endpoint may be identified within a grid of points defined on the at least one substrate. The at least one substrate may comprise a printed circuit board substrate, an integrated circuit die substrate, or some other type of substrate.

At block 1904, for each of the prospective routes identified at block 1902, a temperature characteristic associated with the prospective route is determined. For example, the operations of block 1904 may involve determining, for each point of a set of points along a corresponding prospective route, a temperature correlation between the point and first and second endpoints associated with the routing of the wire.

In some aspects, the determination of the temperature characteristics associated with the prospective routes may involve: determining, for each of the points of a grid of points, a temperature characteristic of the point; generating a spatial correlation matrix corresponding to the grid of points based on the temperature characteristics of the points; generating a correlation cofactor matrix based on the spatial correlation matrix, wherein the correlation cofactor matrix correlates, for each of the points of the grid of points, the temperature characteristic of the point with the temperature characteristics of first and second endpoints associated with the routing of the wire; and determining, for each prospective route, a temperature correlation between the prospective route and the first and second endpoints based on the correlation cofactor matrix.

At block 1906, one of the prospective routes is selected based on the temperature characteristics determined at block 1904. In some aspects, the selection of the route comprises determining which prospective route has a highest temperature correlation with first and second endpoints associated with the routing of the wire. In some aspects, the selection of the route comprises determining which set of points of a plurality of different sets of points associated with the different prospective routes has a highest collective temperature correlation with first and second endpoints associated with the routing of the wire. In some aspects, the selection of the route comprises rejecting any of the prospective routes that pass through an area of the at least one substrate associated with a temperature that exceeds a threshold temperature. In some aspects, the selection of the route comprises rejecting any of the prospective routes that pass through an area of the at least one substrate associated with a temperature that falls below a threshold temperature.

At block 1908, an indication of the selected route is stored in a memory device. For example, the indication may be stored along with other routing data and other circuit data associated with a circuit design.

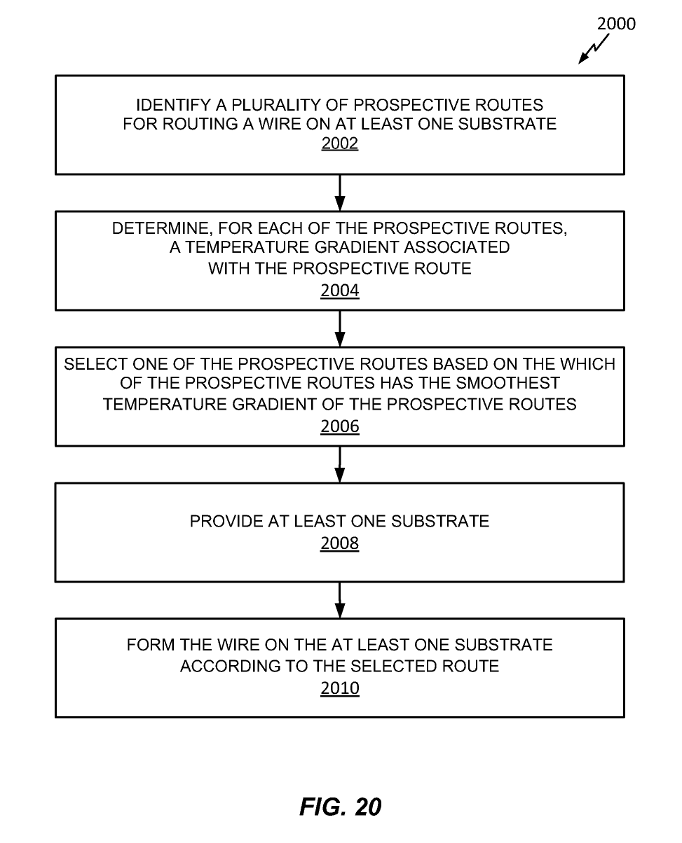

FIG. 20 illustrates a process 2000 for preparing at least one substrate having a wire formed thereon along a selected route associated with a smoothest temperature gradient from among a plurality of prospective routes. One or more operations of the process 2000 may take place within a processing circuit 1810 (FIG. 18), which may be located in a circuit design tool or some other suitable apparatus. In another aspect, one or more operations of the process 2000 may be implemented by the circuit design system 1700 illustrated in FIG. 17. Of course, in various aspects within the scope of the disclosure, the process 2000 may be implemented by any suitable apparatus capable of supporting wire routing operations.

At block 2002, the prospective routes for routing the wire on the at least one substrate are identified. In some aspects, the operations of block 2002 may correspond to the operations of block 1902. Also as discussed above, the at least one substrate may comprise a printed circuit board substrate, an integrated circuit die substrate, or some other type of substrate.

At block 2004, for each of the prospective routes identified at block 2002, a temperature gradient associated with the prospective route is determined. In some aspects, the determination of the temperature gradients may comprise determining, for each point of a set of points along a corresponding prospective route, a temperature correlation between the point and first and second endpoints associated with the routing of the wire.

In some aspects, the determination of the temperature gradients may involve: determining, for each of the points of a grid of points, a temperature characteristic of the point; generating a spatial correlation matrix corresponding to the grid of points based on the temperature characteristics of the points; generating a correlation cofactor matrix based on the spatial correlation matrix, wherein the correlation cofactor matrix correlates, for each of the points of the grid of points, the temperature characteristic of the point with the temperature characteristics of first and second endpoints associated with the routing of the wire; and determining, for each prospective route, a temperature correlation between the prospective route and the first and second endpoints based on the correlation cofactor matrix.

At block 2006, one of the prospective routes is selected based on which of the prospective routes has the smoothest temperature gradient of the prospective routes. In some aspects, the selection of one of the prospective routes may comprise determining which prospective route has a highest temperature correlation with first and second endpoints associated with the routing of the wire. In some aspects, the selection of one of the prospective routes may comprise determining which set of points has a highest collective temperature correlation with first and second endpoints associated with the routing of the wire. In some aspects, the selection of one of the prospective routes may comprise rejecting any of the prospective routes that pass through an area of the at least one substrate associated with a temperature that exceeds a threshold temperature. In some aspects, the selection of one of the prospective routes may comprise rejecting any of the prospective routes that pass through an area of the at least one substrate associated with a temperature that falls below a threshold temperature.

In some aspects, the smoothest temperature gradient may correspond to a highest correlation in temperature with the first and second endpoints along the selected route. In some aspects, the smoothest temperature gradient may correspond to a highest consistency of a temperature characteristic along the selected route.

At block 2008, an appropriate manufacturing operation provides (e.g., forms or acquires) the at least one substrate. For example, a fabrication system may form at least one substrate for an integrated circuit die or form at least one substrate for a printed circuit board.

At block 2010, an appropriate manufacturing operation forms the wire on the at least one substrate according to the selected route. For example, based on circuit design data that indicates the path of the selected route, a fabrication system may form the wire on at least one substrate for an integrated circuit die or on at least one substrate for a printed circuit board.

In some aspects, the selected route does not traverse any area of the at least one substrate associated with a temperature that exceeds a threshold temperature. In some aspects, the selected route does not traverse any area of the at least one substrate associated with a temperature that falls below a threshold temperature.

In some aspects, the selected route may comprise a first endpoint, a second endpoint, and a branch point, whereby the branch point is associated with a highest temperature correlation with the first and second endpoints from among a plurality of prospective branch points located between the first and second endpoints.

In some aspects, the at least one substrate may define a plurality of routing layers (e.g., stacked substrates). In this case, the smoothest temperature gradient may be associated with one of the prospective routes that traverses at least two of the plurality of routing layers. Also, the smoothest temperature gradient may be associated with one of the prospective routes that traverses a via between at least two the plurality of routing layers. Furthermore, the smoothest temperature gradient may be associated with one of the prospective routes that reverses course.

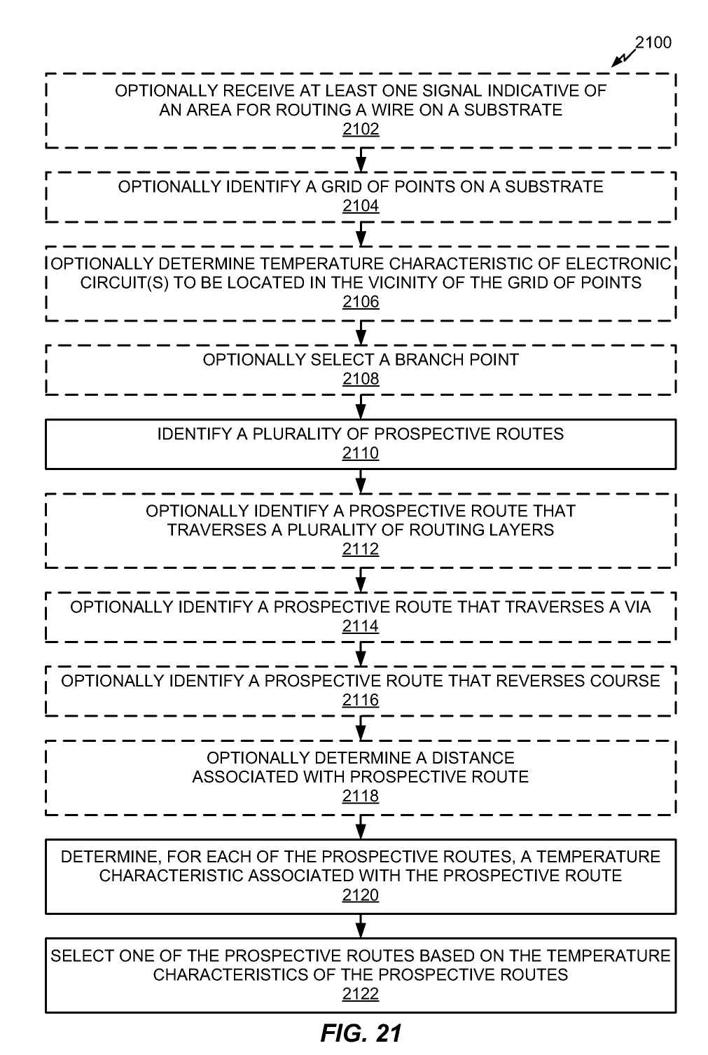

FIG. 21 illustrates a process 2100 that includes additional aspects of a wire routing method in accordance with some aspects of the disclosure. The process 2100 may take place within a processing circuit 1810 (FIG. 18), which may be located in a circuit design tool or some other suitable apparatus. In another aspect, the process 2100 may be implemented by the circuit design system 1700 illustrated in FIG. 17. Of course, in various aspects within the scope of the disclosure, the process 2100 may be implemented by any suitable apparatus capable of supporting wire routing operations.

At optional block 2102, at least one signal indicative of an area for routing a wire on a substrate (e.g., a single layer substrate or a multi-layer substrate) may be received. For example, a receiver of an apparatus (e.g., a receiver circuit in a bus interface or a processing circuit) may receive a signal (e.g., that comprises a message) from another apparatus (e.g., a memory device or a transmitter circuit) that includes information that indicates the area for routing the wire.

At optional block 2104, a grid of points may be identified on a substrate. For example, the grid may be defined within a specified routing area.

At optional block 2106, at least one temperature characteristic of at least one electronic circuit to be located in a vicinity of the grid of points may be determined. For example, a simulation may be conducted or measurements made to determine the temperatures that are to be expected in the vicinity of the electronic circuit(s) during operation of the electronic circuit(s). In this case, a determination of the temperature characteristics of the points (e.g., at block 2120) may be based on the at least one temperature characteristic of the at least one electronic circuit.

At optional block 2108, a branch point may be selected. For example, in the event a clock tree is being routed, a branch point of a plurality of prospective branch points between first and second endpoints may be selected based on which prospective branch point has a highest temperature correlation with the first and second endpoints.

At block 2110, the prospective routes are identified. In some aspects, the operations of block 2110 may correspond to the operations of block 1902 discussed above.

At optional block 2112, at least one prospective route that traverses at least two of a plurality of routing layers may be identified. In this case, selection of the route (e.g., at block 2122) may involve applying a weighting factor to each prospective route that traverses at least two of the plurality of routing layers.

At optional block 2114, at least one prospective route that traverses a via between at least two of a plurality of routing layers may be identified. In this case, selection of the route may involve applying a weighting factor to each prospective route that traverses a via between at least two of the plurality of routing layers.

At optional block 2116, at least one prospective route that reverses course may be identified. In this case, selection of the route may involve applying a weighting factor to each prospective route that reverses course.

At optional block 2118, for each of the prospective routes, a distance associated with the prospective route may be identified. In this case, selection of the route may be based on the distances associated with the prospective routes.

At block 2120, for each of the identified prospective routes, a temperature characteristic associated with the prospective route is determined. In some aspects, the operations of block 2120 may correspond to the operations of block 1904 discussed above.

At block 2122, one of the prospective routes is selected based on the temperature characteristics determined at block 2120. In some aspects, the operations of block 2122 may correspond to the operations of block 1906 discussed above.

In view of the above, a routing scheme practiced in accordance with the teaching herein may advantageously provide more effective routing as compared to conventional routing schemes. For example, U.S. Pat. Nos. 7,155,686 and 8,209,651 are directed to a significantly different scheme whereby a wire is moved if the wire generates too much heat. Also, while U.S. Pat. Nos. 6,775,710 and 7,725,861 use the terms “temperature” and “hot spots” in the context of routing, these patents do not perform any routing based on actual temperature.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein. Additional elements, components, steps, and/or functions may also be added or not utilized without departing from the disclosure.

While features of the disclosure may have been discussed relative to certain implementations and figures, all implementations of the disclosure can include one or more of the advantageous features discussed herein. In other words, while one or more implementations may have been discussed as having certain advantageous features, one or more of such features may also be used in accordance with any of the various implementations discussed herein. In similar fashion, while exemplary implementations may have been discussed herein as device, system, or method implementations, it should be understood that such exemplary implementations can be implemented in various devices, systems, and methods.

Also, it is noted that at least some implementations have been described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function. The various methods described herein may be partially or fully implemented by programming (e.g., instructions and/or data) that may be stored in a machine-readable, computer-readable, and/or processor-readable storage medium, and executed by one or more processors, machines and/or devices.

Those of skill in the art would further appreciate that the various illustrative logical blocks, modules, circuits, and algorithm steps described in connection with the implementations disclosed herein may be implemented as hardware, software, firmware, middleware, microcode, or any combination thereof. To clearly illustrate this interchangeability, various illustrative components, blocks, modules, circuits, and steps have been described above generally in terms of their functionality. Whether such functionality is implemented as hardware or software depends upon the particular application and design constraints imposed on the overall system.

Within the disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the disclosure, without limitation as to the type of electronic circuits, as well as software implementations of information and instructions that, when executed by a processor, enable the performance of the functions described in the disclosure.

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

Accordingly, the various features associate with the examples described herein and shown in the accompanying drawings can be implemented in different examples and implementations without departing from the scope of the disclosure. Therefore, although certain specific constructions and arrangements have been described and shown in the accompanying drawings, such implementations are merely illustrative and not restrictive of the scope of the disclosure, since various other additions and modifications to, and deletions from, the described implementations will be apparent to one of ordinary skill in the art. Thus, the scope of the disclosure is only determined by the literal language, and legal equivalents, of the claims which follow.

What is claimed is:

1. A routing apparatus, comprising:
a memory device;
a processing circuit coupled to the memory device and configured to:
identify a plurality of prospective routes for routing a wire through at least one substrate;
determine, for each of the prospective routes, a temperature characteristic associated with the prospective route;
select one of the prospective routes based on the temperature characteristics of the prospective routes; and
store an indication of the selected route in the memory device.

2. The apparatus of claim 1, wherein:
the routing of the wire is between a first endpoint and a second endpoint; and
the processing circuit is further configured to select one of the prospective routes by determining which prospective route has a highest temperature correlation with the first and second endpoints.

3. The apparatus of claim 1, wherein:
the routing of the wire is between a first endpoint and a second endpoint; and
the processing circuit is further configured to determine the temperature characteristics by determining, for each point of a set of points along a corresponding prospective route, a temperature correlation between the point and the first and second endpoints.

4. The apparatus of claim 3, wherein the processing circuit is further configured to select one of the prospective routes by determining which set of points has a highest collective temperature correlation with the first and second endpoints.

5. The apparatus of claim 1, wherein the processing circuit is further configured to select one of the prospective routes by rejecting any of the prospective routes that pass through an area of the at least one substrate associated with a temperature that exceeds a threshold temperature.

6. The apparatus of claim 1, wherein the processing circuit is further configured to select one of the prospective routes by rejecting any of the prospective routes that pass through an area of the at least one substrate associated with a temperature that falls below a threshold temperature.

7. The apparatus of claim 1, wherein the processing circuit is further configured to:
identify a grid of points on the at least one substrate; and
identify the plurality of prospective routes by identifying routes within the grid of points,
wherein the routing of the wire is between a first endpoint and a second endpoint within the grid of points.

8. The apparatus of claim 7, wherein the processing circuit is further configured to determine the temperature characteristics associated with the prospective routes by:
determining, for each of the points of the grid of points, a temperature characteristic of the point;
generating a spatial correlation matrix corresponding to the grid of points based on the temperature characteristics of the points;
generating a correlation cofactor matrix based on the spatial correlation matrix, wherein the correlation cofactor matrix correlates, for each of the points of the grid of points, the temperature characteristic of the point with the temperature characteristics of the first and second endpoints; and
determining, for each prospective route, a temperature correlation between the prospective route and the first and second endpoints based on the correlation cofactor matrix.

9. The apparatus of claim 8, wherein the processing circuit is further configured to select one of the prospective routes by determining which prospective route has a highest temperature correlation with the first and second endpoints.

10. The apparatus of claim 8, wherein the processing circuit is further configured to:
determine at least one temperature characteristic of at least one electronic circuit to be located in a vicinity of the grid of points; and
determine the temperature characteristics of the points based on the at least one temperature characteristic of the at least one electronic circuit.

11. The apparatus of claim 1, wherein the processing circuit is further configured to:
determine, for each of the prospective routes, a distance associated with the prospective route; and
select one of the prospective routes based on the distances associated with the prospective routes.

12. The apparatus of claim 1, wherein:
the routing of the wire is between a first endpoint and a second endpoint; and
the processing circuit is further configured to select one branch point of a plurality of prospective branch points between the first and second endpoints based on which prospective branch point has a highest temperature correlation with the first and second endpoints.

13. The apparatus of claim 1, wherein:
the at least one substrate comprises a plurality of stacked substrates; and
the processing circuit is further configured to identify the plurality of prospective routes over the plurality of stacked substrates.

14. The apparatus of claim 1, wherein:
the at least one substrate defines a plurality of routing layers; and
the processing circuit is further configured to:
identify at least one prospective route that traverses at least two of the plurality of routing layers, and
select one of the prospective routes by applying a weighting factor to each prospective route that traverses at least two of the plurality of routing layers.

15. The apparatus of claim 1, wherein:
the at least one substrate defines a plurality of routing layers; and
the processing circuit is further configured to:
identify at least one prospective route that traverses a via between at least two of the plurality of routing layers, and
select one of the prospective routes by applying a weighting factor to each prospective route that traverses a via between at least two of the plurality of routing layers.

16. The apparatus of claim 1, wherein the processing circuit is further configured to:
identify at least one prospective route that reverses course; and
select one of the prospective routes by applying a weighting factor to each prospective route that reverses course.

17. The apparatus of claim 1, wherein the at least one substrate comprises a printed circuit board substrate.

18. The apparatus of claim 1, wherein the at least one substrate comprises an integrated circuit die substrate.

19. A routing method, comprising:
receiving at least one signal indicative of an area for routing a wire through at least one substrate;
identifying a plurality of prospective routes for routing the wire within the area;
determining, for each of the prospective routes, a temperature characteristic associated with the prospective route;
selecting one of the prospective routes based on the temperature characteristics of the prospective routes; and
storing an indication of the selected route.

20. The method of claim 19, wherein:
the routing of the wire is between a first endpoint and a second endpoint; and
the selection of one of the prospective routes comprises determining which prospective route has a highest temperature correlation with the first and second endpoints.

21. The method of claim 19, wherein:
the routing of the wire is between a first endpoint and a second endpoint; and
the determination of the temperature characteristics comprises determining, for each point of a set of points along a corresponding prospective route, a temperature correlation between the point and the first and second endpoints.

22. The method of claim 21, wherein the selection of one of the prospective routes comprises determining which set of points has a highest collective temperature correlation with the first and second endpoints.

23. The method of claim 19, wherein the selection of one of the prospective routes comprises rejecting any of the prospective routes that pass through an area of the at least one substrate associated with a temperature that exceeds a threshold temperature.

24. The method of claim 19, wherein the selection of one of the prospective routes comprises rejecting any of the prospective routes that pass through an area of the at least one substrate associated with a temperature that falls below a threshold temperature.

25. A routing apparatus, comprising:
means for identifying a plurality of prospective routes for routing a wire through at least one substrate;
means for determining, for each of the prospective routes, a temperature characteristic associated with the prospective route;
means for selecting one of the prospective routes based on the temperature characteristics of the prospective routes; and
means for storing an indication of the selected route.

26. The apparatus of claim 25, wherein:
the routing of the wire is between a first endpoint and a second endpoint; and
the means for selecting one of the prospective routes is configured to determine which prospective route has a highest temperature correlation with the first and second endpoints.

27. The apparatus of claim 25, wherein:
the routing of the wire is between a first endpoint and a second endpoint; and
the means for determining a temperature characteristic is configured to determine, for each point of a set of points along a corresponding prospective route, a temperature correlation between the point and the first and second endpoints.

28. The apparatus of claim 27, wherein the means for selecting one of the prospective routes is configured to determine which set of points has a highest collective temperature correlation with the first and second endpoints.

29. The apparatus of claim 25, wherein the means for selecting one of the prospective routes is configured to reject any of the prospective routes that pass through an area of the at least one substrate associated with a temperature that exceeds a threshold temperature.

30. A substrate having a wire formed thereon along a selected route associated with a smoothest temperature gradient from among a plurality of prospective routes, the substrate prepared by a process comprising:
identifying the plurality of prospective routes for routing the wire on the substrate;
determining, for each of the prospective routes, a temperature gradient associated with the prospective route;
selecting one of the prospective routes based on which of the prospective routes has the smoothest temperature gradient of the prospective routes;
providing the substrate; and
forming the wire on the substrate according to the selected route.
